(19) United States
(12) Patent Application Publication
(10) Pub. No.: US 2005/0133823 A1
(43) Pub. Date: Jun. 23, 2005

(54) Method and apparatus for forming a wiring, wiring board, and ink set

(75) Inventors: Takashi Mori, Tokyo (JP); Kazuo Iwata, Kanagawa (JP); Yuji Tsuruoka, Kanagawa (JP); Osamu Nishiwaki, Kanagawa (JP); Hidehito Takayama, Kanagawa (JP); Eiichi Motai, Kanagawa (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 11/000,012

(22) Filed: Dec. 1, 2004

(30) Foreign Application Priority Data
Dec. 22, 2003 (JP) 2003-424988

(51) Int. Cl. H05K 1/09

(52) U.S. Cl. 257/200

(57) ABSTRACT

A method for forming a wiring according to the present invention includes supplying to a substrate a first liquid containing a first component to form a first pattern and a second liquid containing a second component to form a second pattern to come into contact with each other, the second component causing interfacial aggregation in a contact area with the first component when brought into contact with the first component, and forming a wiring pattern consisting of the first pattern and the second pattern on the substrate.

### BACKGROUND OF THE INVENTION

1. Field of the Invention

The present invention relates to a method for forming a wiring, a wiring board, an apparatus for forming a wiring, and an ink set, all of which are used to form a wiring on a substrate.

2. Related Background Art

A wiring board having mounted thereon semiconductor circuits such as an LSI or various electronic parts is used in an electronic device, a communication apparatus, a computer, or the like. There are a variety of wiring boards, for example, a board including a ceramic substrate, a board made of a composite material of a reinforcing material such as a glass fiber with a synthetic resin such as an epoxy resin, and a board using as a substrate a flexible film made of a polyester resin, aramid resin, or the like. The wiring board is also classified in terms of the number of circuit layers, into a single-layer board where a single circuit layer is formed on the same surface of a double-sided or single-sided board and a multilayer board where plural circuit layers are formed on the same surface thereof. A suitable wiring board is chosen on a case-by-case basis according to its applications or requisite characteristics. Those wiring boards each have a conductor circuit and their wiring patterns are designed with a high degree of integration in response to recent tendencies for downsized apparatuses and higher-performance semiconductors.

The formation of the wiring pattern on the wiring board is generally carried out by a subtractive process. The circuit formation through the subtractive process requires a drilling step, an electroless plating step, a patterning step with a dry film or the like, an electroplating step, an etching step, a solder peeling step, and the like. This process necessitates a number of steps and a long time for each of the steps, leading to a high ratio of a process cost to a manufacturing cost. A big problem of how to reduce the process cost remains to be solved in the field of wiring board. In particular, the above holds true for a multilayer wiring board. There arises another problem about treatment of waste liquid discharged in a plating step or etching step.

In order to solve the above-mentioned problems, Japanese Patent Application Laid-Open No. H11-163499 discloses a method for forming a wiring board, which includes simultaneously forming a conducting pattern and an insulating pattern on a surface of a substrate by an ink-jet system to thereby form a wiring pattern.

FIG. 4 is a sectional view showing a wiring pattern (conducting pattern and insulating pattern) formed by the conventional method for forming a wiring. If a wiring is formed by the ink-jet system of the conventional technique, as shown in FIG. 4, a bleeding 7 occurs in a contact area between the conducting pattern and the insulating pattern. The bleeding may bring any parts into conduction in an unintended portion.

### SUMMARY OF THE INVENTION

The present invention has been made in light of the above-mentioned problems and has a main object to provide a method for forming a wiring, a wiring board, an apparatus for forming a wiring, and an ink set, which can prevent bleeding in a contact area between a conducting pattern and an insulating pattern and form a fine wiring pattern even if the conducting pattern and the insulating pattern are simultaneously formed on a substrate. It is another object of the present invention to provide a method for forming a wiring, a wiring board, an apparatus for forming a wiring, and an ink set, which solve various problems in that formation of a wiring requires a complicated wiring pattern forming step, a great number of steps, a long process time, etc., realize a low process cost, and discharge no harmful plating waste liquid nor etching waste liquid.

### BRIEF DESCRIPTION OF THE DRAWINGS

FIG. 1A shows a wiring pattern according to Example 1 of the present invention, FIG. 1B is a sectional view taken along the line 1B-1B of FIG. 1A, and FIG. 1C is a sectional view taken along the line 1C-1C of FIG. 1A;

FIG. 2A shows a wiring pattern in a second layer according to Example 2 of the present invention, and FIG. 2B is a sectional view taken along the line 2B-2B of FIG. 2A;

FIG. 3A shows a wiring pattern in a third layer according to Example 2 of the present invention, and FIG. 3B is a sectional view taken along the line 3B-3B of FIG. 3A;

FIG. 4 is a sectional view showing a wiring pattern formed by a conventional method for forming a wiring;

FIG. 5 is a schematic diagram showing an apparatus for forming a wiring according to the present invention; and

FIG. 6A is a schematic diagram showing integrated first and second liquid reservoir containers, and FIG. 6B is a schematic diagram showing separated first and second liquid reservoir containers.

### DESCRIPTION OF THE PREFERRED EMBODIMENTS

According to the present invention, when a conducting pattern which is conductive and an insulating pattern which is insulative are set as a first pattern and a second pattern, respectively, for example, interfacial aggregation occurs in a contact area between the conducting pattern and the insulating pattern to thereby prevent bleeding from occurring between the conducting pattern and the insulating pattern and form a fine wiring pattern.

The term “interfacial aggregation” used herein refers to a state in which when two different liquids come into contact with each other, components in the two liquids aggregate in a small contact area (on the order of several hundreds of nm to several μm) and thus the two different liquids are present across the small area.

In the present invention, meant by the term “interfacial aggregation” is a phenomenon that aggregation occurs in a contact area formed between a first liquid forming a conducting pattern and a second liquid forming an insulating pattern when the two liquids contact with each other, leading to an interface. The present invention makes use of a state where an area of the first liquid rich in a first liquid component and an area of the second liquid rich in a second liquid component are separated from each other across an interface aggregation area. If two polymers, i.e., a first polymer in the first liquid and a second polymer in the second liquid are incompatible (immiscible) with each other, the first liquid and the second liquid are separated, upon contacting with each other, into two immiscible phases across an interface boundary. In the present invention, the “interfacial aggregation” includes such an interface.

Further, the present invention requires neither a screen printer nor an etching apparatus and thus solves various problems in that formation of a wiring requires a complicated wiring pattern forming step, a great number of steps, a long process time, etc., and enables formation of a wiring board at a low process cost.

In addition, the present invention relates to an environmentally-friendly method for forming a wiring, wiring board, apparatus for forming a wiring, and ink set, on account of discharging no harmful plating waste liquid nor etching waste liquid.

As a method for forming a wiring pattern composed of a conducting pattern and an insulating pattern on a substrate, although not particularly limited, an ink-jet system that have been widely adopted in recent years in a printer etc. of a personal computer is preferably used.

With the ink-jet system, the size of a particle forming a wiring pattern is adjusted to thereby set a resolution in a range of 200 to 1,000 dpi. Thus, a wiring pattern can be made so fine that its pattern width or pitch is about 100 μm. Accordingly, it is possible to meet a need for high-density wiring patterns to a satisfactory level as well. Also, an ink-jet printer is connected with a computer such as a personal computer, and wiring pattern shape information inputted to the computer is referred to, whereby the conducting pattern and the insulating pattern can be simultaneously formed in one step. As compared with any conventional method for forming a wiring pattern through a number of steps for a long time, the present invention enables wiring pattern formation much more easily in a short time. In addition, the present invention necessitates neither a screen printer nor an etching apparatus, and only requires: a wiring pattern forming apparatus of an ink-jet system interfacing with a computer; and a simple drier, resulting in an inexpensive apparatus.

According to the present invention, interfacial aggregation occurs in a contact area between the conducting pattern and the insulating pattern, making it possible to prevent bleeding from occurring between the conducting pattern and the insulating pattern and form a fine wiring pattern.

1. Structure of Apparatus for Forming Wiring

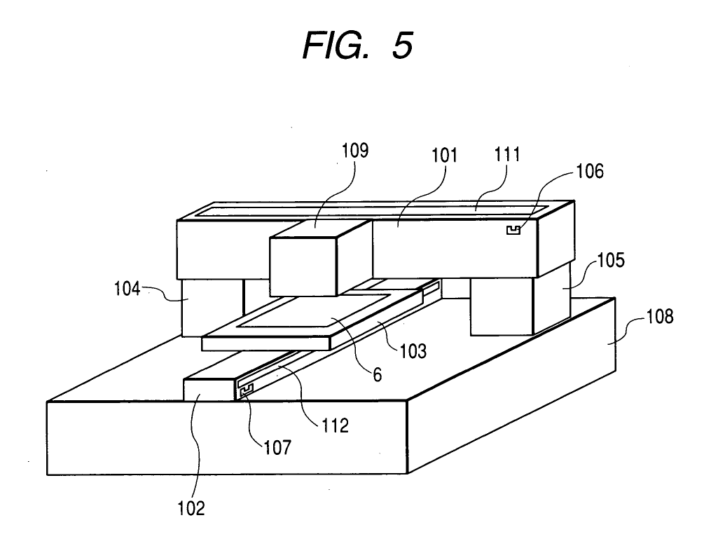

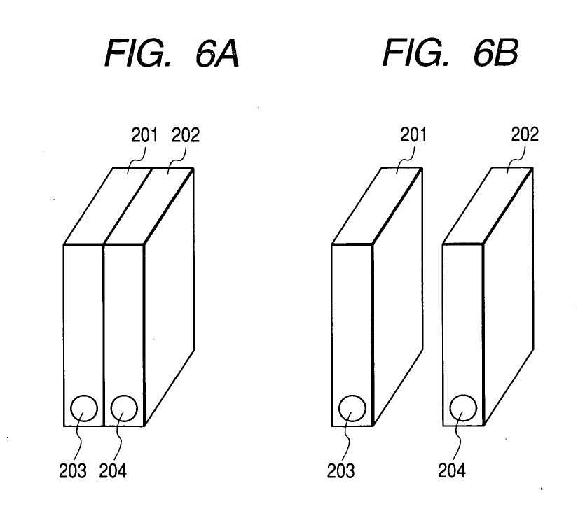

FIG. 5 is a schematic diagram showing an apparatus for forming a wiring using an ink-jet system according to an embodiment of the present invention. FIGS. 6A and 6B show liquid reservoir containers for a first liquid and/or a second liquid. The apparatus for forming a wiring used in this embodiment includes: a head (not shown) for discharging the first liquid and the second liquid on a substrate 6; a carriage 109 on which a first liquid reservoir container 201 for the first liquid and a second liquid reservoir container 202 for the second liquid are mounted; and a stage 103 having the substrate 6 as a recording medium mounted thereon. FIG. 6A is a schematic diagram showing the integrated first and second liquid reservoir containers, and FIG. 6B is a schematic diagram showing the separated first and second liquid reservoir containers. The first liquid reservoir container 201 for the first liquid is provided with a first supply port 203 for supplying the first liquid to the head. The second liquid reservoir container 202 for the second liquid is provided with a second supply port 204 for supplying the second liquid to the head. A carriage (CR) linear motor 101 and a line feed (LF) linear motor 102 are provided as means for moving the carriage 109 and means for moving the substrate 6, respectively. The LF linear motor 102 is fixed to a platen 108 while maintaining its high rigidity. Even when the stage 103 is moved, the surface of the stage on which the substrate 6 is mounted is kept parallel with the platen surface all the time. On the other hand, the CR linear motor 101 is fixed onto the platen 108 through bases 104 and 105 while maintaining its high rigidity and adjusted such that the carriage 109 is moved in parallel with the platen surface, i.e., the stage surface. The CR linear motor 101 and the LF liner motor 102 have built-in linear encoders 111 and 112, and origin sensors 106 and 107, respectively. The linear encoders 111, 112 are used for inputting a servo control signal at the time of moving the respective linear motors, and in addition, the linear encoder 111 on the CR linear motor 101 side is used for controlling a discharge timing of the first liquid and second liquid. This apparatus for forming a wiring is connected to a computer (not shown) and discharges the first liquid and second liquid from the head based on wiring pattern shape information data sent from the computer to thereby simultaneously form the conducting pattern and the insulating pattern on a surface of the substrate 6.

2. Substrate

As regards a shape of the substrate 6 used in the present invention, the substrate takes a planar shape, e.g., a film-, sheet-, or plate-like shape. The film- or sheet-like shape is particularly preferred for forming wiring pattern layers in succession. Alternatively, a curved surface may be adopted instead of a flat surface insofar as the wiring pattern can be formed through the ink-jet system. Regarding a material thereof, the substrate includes: a thermoplastic resin film such as a polyester film, an aromatic polyamide film, or a polyimide film; woven or non-woven cloth of glass fibers, polyester fibers, or aromatic polyamide fibers impregnated with a thermoplastic resin or epoxy resin and cured into a sheet-like shape; a plate-like one like a glass epoxy laminate used for general wiring boards; and a substrate with permeability such as paper or cloth.

3. First Liquid and Second Liquid

The first liquid for forming the conducting pattern used in the present invention contains water and a conductive material. In general, preferably adopted as water used for preparing the first liquid according to the present invention is one prepared by using industrial water as a raw material and removing a cation and anion through deionization exchange treatment. The amount of water in the first liquid is determined in a wide range according to kinds of water-soluble organic solvents as described later and their ratios, and characteristics required of the first liquid; the water content in the first liquid generally ranges from 10 to 98 wt %, preferably 40 to 90 wt %.

Examples of the conductive material, which is a first component, used in the first liquid include a metal ultra-fine particle having an average particle size of about 1 to 100 nm and formed by laser abrasion. The metal ultra-fine particle is represented by indium tin oxide (ITO), tin oxide (SnO₂), or the like.

The second liquid for forming the insulating pattern used in the present invention contains water, an insulating material, and a second component. The second component is an alkali aqueous solution. If the second component contacts with the conductive material used in the first liquid, a difference in pH between them induces an aggregation and precipitation reaction to cause interfacial aggregation in a contact region, preventing bleeding from occurring between the first liquid and second liquid. The first liquid and the second liquid are separated from each other. Then, the second component is vaporized through heat-curing treatment (post-treatment). Water used in the second liquid may be water as used in the first liquid.

Given as an example of the substance used as the second component is any polymer. Examples of such a polymer include an anionic water-soluble polymer and volatile amine. Specific examples of the second component include: the anionic water-soluble polymer; the volatile amine (ammonium salt); and ammonium hydroxide. The insulating material includes a nonionic polymer. Specific examples of the nonionic polymer include solder resist mainly containing an epoxy resin or the like.

4. Method for Forming Conducting Pattern and Insulating Pattern

### EXAMPLE 1

A method for forming a conducting pattern and insulating pattern according to Example 1 of the present invention will be described.

In this example, the conducting pattern and the insulating pattern are formed on an insulating substrate at almost the same time by using the aforementioned apparatus for forming the wiring, and discharging from a head the first liquid in the first liquid reservoir container and second liquid in the second liquid reservoir container of the apparatus for forming the wiring. As the insulating substrate, a 100 μm-thick polyimide film was used. The first liquid contains: tin oxide (SnO₂) particles having an average particle size of 100 nm or less as the conductive material in an amount of 10 wt %; and water in an amount of 90 wt %. The second liquid contains: 10 wt %-ammonium hydroxide as the second component; 10 wt %-epoxy resin based solder resist; and 80 wt %-water.

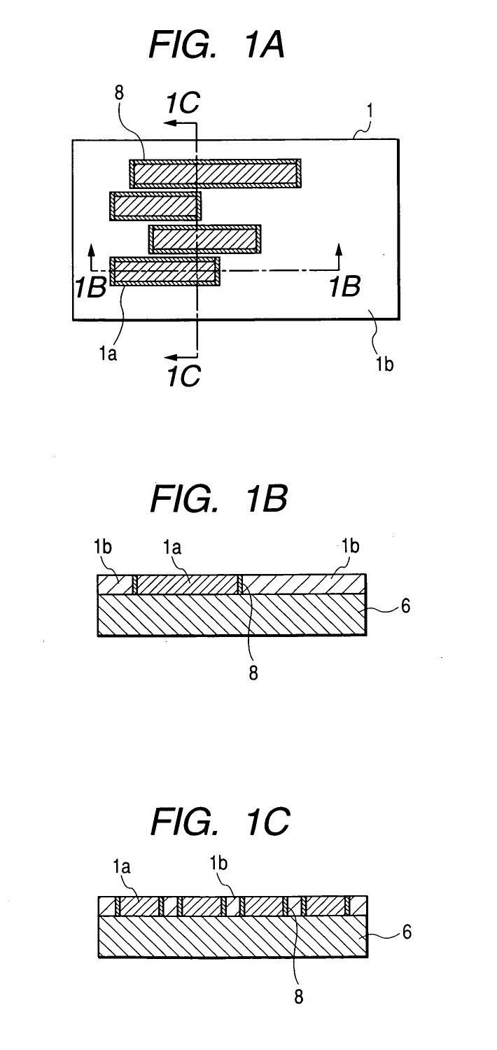

FIG. 1A shows a wiring pattern according to the present invention. In FIG. 1A, reference numeral 1 denotes a wiring pattern in a first layer formed on the substrate 6; 1a, a conducting pattern with a width of about 150 μm in the first layer; and 1b, an insulating pattern in the first layer. Here, interfacial aggregation occurs in a contact area between tin oxide (SnO₂) as the conductive material in the first liquid, which forms the conducting pattern 1a, and ammonium hydroxide as the second component in the second liquid, which forms the insulating pattern 1b. In other words, an aggregation and precipitation reaction is induced by a difference in pH between tin oxide (SnO₂) particles as conductive metal ultra-fine particles stable in an acidic region (pH<7) and alkaline, highly volatile ammonium hydroxide. FIG. 1A shows how an area 8 in which the interfacial aggregation occurs prevents bleeding from occurring between the conducting pattern formed by use of the first liquid and the insulating pattern formed by use of the second liquid, and the conducting pattern 1a and the insulating pattern 1b are formed in a separated form.

FIG. 1B is a sectional view taken along the line 1B-1B of FIG. 1A. The conducting pattern 1a and the insulating pattern 1b are formed with the same thickness on the substrate 6. In this example, the wiring pattern thickness was set to about 25 μm. In the sectional view of FIG. 1B as well, the interfacial aggregation occurs in a contact area between the conducting pattern 1a and the insulating pattern 1b on the substrate 6 and prevents bleeding from occurring between the two patterns.

FIG. 1C is a sectional view taken along the line 1C-1C of FIG. 1A. Reference symbol 1a denotes the conducting pattern and reference symbol 1b denotes the insulating pattern.

Upon completion of formation of the wiring pattern in the first layer, the resultant is subjected to heat treatment in a heating furnace (not shown in FIG. 5) following the treatment in the apparatus for forming the wiring to thereby dry a solvent or cure a binder. Although heating conditions vary depending on components in the first liquid and second liquid, the heat-curing treatment is effected at 150° C. for 60 minutes in this example. Note that, the ammonium hydroxide as the second component in the second liquid is vaporized through this heat-curing treatment.

If the first liquid and the second liquid are quick-drying ones, continuous wiring pattern formation with the ink-jet system is allowed since the second component is vaporized without heat-curing treatment.

### EXAMPLE 2

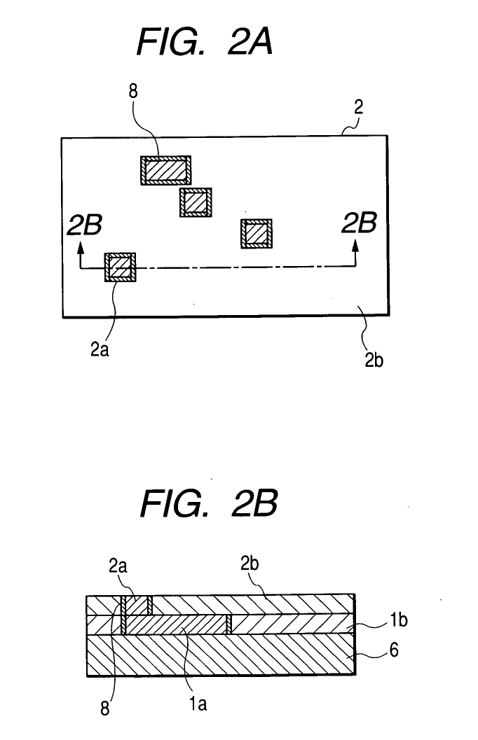

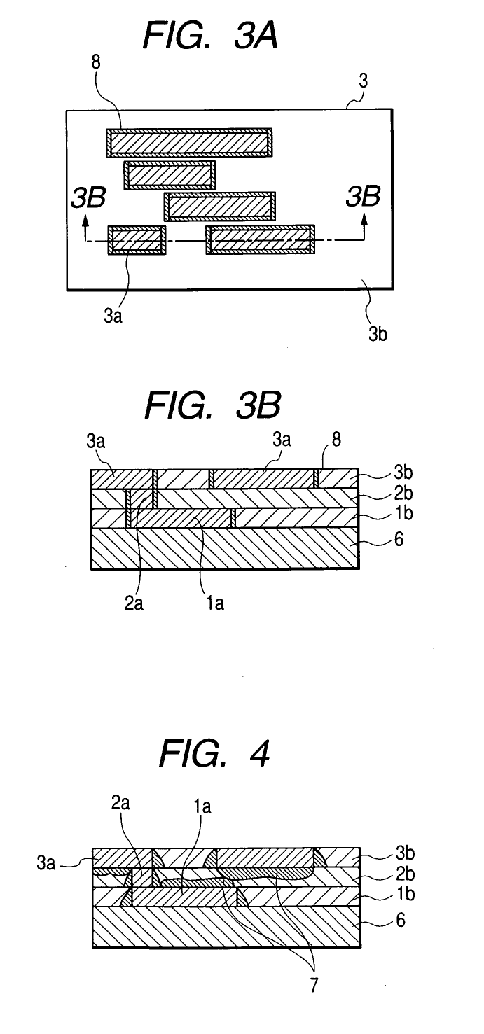

Referring to FIG. 2A to 2B and 3A to 3B, description is given of a wiring board where a multilayer circuit is formed according to Example 2 of the present invention. Note that the first liquid, second liquid, apparatus for forming the wiring, curing treatment, etc. used in this example are the same as in Example 1, and the wiring pattern in the first layer formed on the substrate 6 is formed as shown in FIGS. 1A to 1C.

FIG. 2A shows a state where a wiring pattern in a second layer is formed on the wiring pattern in the first layer of FIGS. 1A to 1C. In FIG. 2A, reference symbol 2a denotes a conducting pattern in the second layer, which is used for connecting between the wiring pattern in the first layer and a wiring pattern in a third layer to thereby establish continuity therebetween. Denoted by 2b is an insulating pattern in the second layer. The wiring pattern in the second layer is formed on the wiring pattern in the first layer that have undergone heat-curing treatment. Hence, the wiring patterns in the first layer and second layer are formed without being mixed.

FIG. 2B is a sectional view taken along the line 2B-2B of FIG. 2A. The wiring patterns (conducting pattern 2a and insulating pattern 2b) in the second layer are formed on the wiring patterns (conducting pattern 1a and insulating pattern 1b) in the first layer, and the conducting pattern 2a in the second layer along the line 2B-2B is formed on the conducting pattern 1a in the first layer along the line 1B-1B so that the conducting pattern 2a overlies the conducting pattern 1b. The interfacial aggregation occurs in a contact area between the conducting pattern 2a and the insulating pattern 2b, and an area 8 in which the interfacial aggregation occurs prevents bleeding from occurring between the conducting pattern 2a and the insulating pattern 2b, and the conducting pattern 2a and the insulating pattern 2b are formed in a separated form. Upon completion of formation of the wiring pattern in the second layer, the heat-curing treatment is carried out again under the conditions described in Example 1.

FIG. 3A shows a state where a wiring pattern in a third layer is formed on the wiring pattern in the second layer of FIGS. 2A to 2B. In FIG. 3A, reference symbol 3a denotes a conducting pattern in the third layer and reference symbol 3b denotes an insulating pattern in the third layer. The wiring pattern in the second layer is formed on the wiring pattern in the second layer that has undergone heat-curing treatment. Hence, the wiring patterns in the second layer and third layer are formed without being mixed.

FIG. 3B is a sectional view taken along the line 3B-3B of FIG. 3A. Sections taken along the line 1B-1B of FIG. 1A, the line 2B-2B of FIG. 2A, and the line 3B-3B of FIG. 3A are the same. Thus, FIG. 3B shows how the wiring patterns (conducting pattern 3a and insulating pattern 3b) in the third layer are formed on the wiring patterns (conducting pattern 2a and insulating pattern 2b) in the second layer, and a part of the conducting pattern 3a in the third layer along the line 3B-3B is formed on the conducting pattern 2a in the second layer along the line 2B-2B. The conducting pattern 2a establishes continuity between the conducting patterns 1a and 3a; the conducting pattern in the second layer establishes continuity between the conducting pattern in the first layer and the conducting pattern in the third layer outside a portion along the line 3B-3B. The interfacial aggregation occurs in a contact area between the conducting pattern 3a and the insulating pattern 3b to prevent bleeding from occurring between both the conducting pattern 3a and the insulating pattern 3b. Upon completion of formation of the wiring pattern in the third layer, the heat-curing treatment is carried out again.

In this way, the present invention is used, and the formation of the conducting pattern and insulating pattern, and the curing treatment are repeated, whereby a multilayer wiring board can be formed where bleeding is prevented in a contact area between the conductive liquid and the insulating liquid. A conducting pattern is formed in an intermediate layer, which establishes continuity between a conducting pattern in an upper layer and a conducting pattern in a lower layer, making it possible to form a wiring board having the same effect as in a through-hole wiring. Thus, a highly reliable multilayer wiring board can be readily obtained without a drilling step or a through-hole plating step.

### EXAMPLE 3

In Example 1, the single-layer circuit is formed using a polyimide-film substrate by way of example. In this example, description is made of an example where a wiring pattern is formed on an absorbent substrate. Note that the first liquid, second liquid, and apparatus for forming the wiring used in this example are the same as those in Example 1.

Similarly to Example 1, the first liquid for forming the conducting pattern and the second liquid for forming the insulating pattern are used to form wiring patterns. Here, the substrate is made of an absorbent substance (e.g., paper or cloth), so water in the first liquid and second liquid is absorbed by the substrate. The interfacial aggregation occurs in a contact area between remaining components on the substrate, i.e., between tin oxide (SnO₂) as the conductive material in the first liquid and ammonium hydroxide as the second component in the second liquid. As a result, it is possible to prevent bleeding from occurring between the conducting pattern formed by use of the first liquid and the insulating pattern formed by use of the second liquid, and to form a fine wiring pattern. With this example, an IC chip such as RFID (radio frequency identification) can be mounted or incorporated on/in a card or label with ease.

This application claims priority from Japanese Patent Application No. 2003-424988 filed on Dec. 22, 2003, which is hereby incorporated by reference herein.

1. A method for forming a wiring, comprising the steps of:
supplying to a substrate a first liquid containing a first component to form a first pattern and a second liquid containing a second component to form a second pattern so as to come into contact with each other, the second component causing interfacial aggregation in a contact area with the first component when brought into contact with the first component; and
forming a wiring pattern consisting of the first pattern and the second pattern on the substrate.

2. A method for forming a wiring according to claim 1, wherein the first component is a conductive material, the first pattern is a conducting pattern, the second liquid containing the second component that causes the interfacial aggregation in the contact area when brought into contact with the conductive material further contains an insulating material, and the second pattern is an insulating pattern.

3. A method for forming a wiring according to claim 2, further comprising the step of vaporizing the second component in the insulating pattern after supplying the second liquid to the substrate to form the insulating pattern on the substrate.

4. A method for forming a wiring according to claim 3, wherein the step of vaporizing the second component is a heat treatment.

5. A method for forming a wiring according to claim 2, wherein the second component in the insulating pattern formed on the substrate by use of the second liquid is vaporized.

6. A method for forming a wiring according to claim 1, wherein the first liquid and the second liquid each contain water and are supplied to the substrate by an ink-jet system.

7. A wiring board, comprising:
a wiring pattern formed by the method for forming a wiring according to claim 1; and
the substrate.

8. An apparatus for forming a wiring, comprising:
a first liquid reservoir container for a first liquid containing a first component to form a first pattern;
a second liquid reservoir container for a second liquid containing a second component to form a second pattern, the second component causing interfacial aggregation in a contact area with the first component when brought into contact with the first component; and
means for supplying to a substrate the first liquid and the second liquid so as to come into contact with each other to form a wiring pattern consisting of the first pattern and the second pattern on the substrate.

9. An apparatus for forming a wiring according to claim 8, wherein the first component is a conductive material, the first pattern is a conducting pattern, the second liquid containing the second component that causes the interfacial aggregation in the contact area when brought into contact with the conductive material further contains an insulating material, and the second pattern is an insulating pattern.

10. An ink set, comprising:
a first liquid containing a first component to form a first pattern; and
a second liquid containing a second component to form a second pattern, the second component causing interfacial aggregation in a contact area with the first component when brought into contact with the first component.

11. An ink set according to claim 10, wherein the first component is a conductive material, the first pattern is a conducting pattern, the second liquid containing the second component that causes the interfacial aggregation in the contact area when brought into contact with the conductive material further contains an insulating material, and the second pattern is an insulating pattern.
